(19) United States
(12) Patent Application Publication
(10) Pub. No.: US 2014/0048134 A1
(43) Pub. Date: Feb. 20, 2014

(54) CONCENTRATOR SOLAR RECEIVER WITH IMPROVED HOMOGENIZER

(71) Applicants: YI-PING LIANG, TAOYUAN COUNTY (TW); HWA-YUH SHIN, TAOYUAN COUNTY (TW); HWEN-FEN HONG, TAOYUAN COUNTY (TW)

(72) Inventors: YI-PING LIANG, TAOYUAN COUNTY (TW); HWA-YUH SHIN, TAOYUAN COUNTY (TW); HWEN-FEN HONG, TAOYUAN COUNTY (TW)

(73) Assignee: ATOMIC ENERGY COUNCIL - INSTITUTE OF NUCLEAR ENERGY RESEARCH, Taoyuan County (TW)

(21) Appl. No.: 13/587,045

(22) Filed: Aug. 16, 2012

(51) Int. Cl. H01L 31/0232

(52) U.S. Cl. 136/259

(57) ABSTRACT

A concentrator solar receiver with an improved homogenizer is revealed. A homogenizer used in a concentrator solar module is improved. Instead of a smooth flat surface, a bottom surface of the homogenizer can be a positively curved surface, a conic solid, or a truncated tapered structure. Moreover, the bottom surface can be a rough surface. Thus not only the glue-overflow problem occurred during adhesion of the homogenizer to the solar cell can be solved, but also the possibility of air bubbles remaining between the glue and the homogenizer is reduced. Therefore the yield rate of a concentrator solar module is improved and the service life of the concentrator solar module is prolonged.

### BACKGROUND OF THE INVENTION

1. Fields of the Invention

The present invention relates to an improved homogenizer, especially to an improved homogenizer of a concentrator solar receiver.

2. Descriptions of Related Art

Solar cells are devices that convert solar energy into electricity using the photoelectric effect. During the power generation process, there is no pollutant and greenhouse gases generated, such as carbon dioxide, nitrogen oxides, sulfur oxides, and etc. Solar energy is a non-consumptive and renewable resource. Due to exhaustion of the earth's resources and the increase of energy cost, solar energy has received great attention in 21 century. Companies and products associated with solar power always attract the gaze of everyone and get capital infusion. Thus, this kind of inexhaustible and nonpolluting solar energy is an ultimate source of green energy that brings prosperity to our lives.

However, to make sustainable long term use of solar energy, there is still a long way to go. The solar power technologies available now still need improvement, such as stability, service life or cost.

Solar cell, also called photovoltaic, converts sunlight into electricity. In order to improve power generation efficiency, concentrator solar modules with mirrors or lenses that concentrate more sunlight are used. Fresnel lens, which is a cheap and lightweight lens with short focal length, is arranged over the solar cell. Thus, large-diameter Fresnel lens is used to concentrate sunlight onto solar cell. After sunlight being focused by the Fresnel lens, it is concentrated and entering a transparent light pipe, also called homogenizer, whose shape is inverted-pyramid. Homogenizer which usually has a smooth flat surface on the bottom is used to make energy of light spot concentrated by the Fresnel lens distribute more evenly. Once the energy of light spot is not homogenized and directly entering onto the solar cell, the photoelectric conversion efficiency is low due to the current crowding effect introduced by the uneven energy distribution. Moreover, since the sunlight incident angle is not fixed and varied with time, the concentrator solar module is used in combination with a sun tracking system. This system timely adjusts the operation angle frequently to get the optimal energy generation. To improve the angle tolerance of solar module and tracking system, homogenizer is used on solar module since it can also increase the tolerance of incident angle. Furthermore, homogenizer can improve the module assembly inaccuracy, too. Thus, it is a component of importance and function.

However, the homogenizer used now includes a bottom surface that is flat and smooth. During the adhesion process of the homogenizer to a solar cell, glue-overflow problem is occurred. That means the glue is pushed out of the connection area toward the perpendicular sides of the homogenizer during adhesion process. The excess glue nearby will lead to loss of light energy. Refer to FIG. 1, after the adhesion of a homogenizer 3 with a flat bottom surface, excess glue 2 is pushed to the perpendicular sides. Thus a part of the glue 2 is attached to the side surfaces of the homogenizer 3. When light is reflected within the homogenizer 3, it should all enter into solar cell which the homogenizer 3 is attached on. But if the sides of homogenizer 3 are stained by glue 2, the light will refract from homogenizer into outside air by the stained area. Thus, the light energy which should all reach to concentrator solar cell 1 is reduced and solar power efficiency is lowered.

Moreover, if there is air between the flat bottom surface of the homogenizer 3 and the glue on the solar cell, air bubbles are formed on the contact surface between the flat bottom and the glue 2 during adhesion process. The air bubbles are difficult to be eliminated. As mentioned above, light passing the homogenizer 3 has already been focused by Fresnel lenses so that the operating temperature is extremely high. Therefore, asides from reducing optical efficiency and causing light leakage problem, the concentrator solar module may suffer irreversible damage due to inflation of the air bubbles by high temperature between the glue 2 and the bottom surface of the homogenizer 3.

In order to solve the problems generated during adhesion process of the homogenizer, there is still room for improvement and a need to provide a concentrator solar receiver with an improved homogenizer.

### SUMMARY OF THE INVENTION

Therefore it is a primary object of the present invention to provide a concentrator solar receiver with an improved homogenizer in which a bottom surface of a homogenizer is not a flat surface. Instead of a flat surface, the bottom surface of the homogenizer is a positively curved surface, a conic solid, or a truncated tapered structure. Thus glue-overflow problem during homogenizer adhesion process can be solved and the adhesion strength between homogenizer and concentrator solar cell is increased. Consequently, the yield rate and stability of the concentrator solar module are further improved.

It is another object of the present invention to provide a concentrator solar receiver with an improved homogenizer in which roughness of the bottom surface of the homogenizer is introduced for increasing contact area between glue and the homogenizer/concentrator solar cell and improving the adhesion strength.

It is a further object of the present invention to provide a concentrator solar receiver with an improved homogenizer in which a bottom surface of a homogenizer is a convex surface. Thus the possibility of remaining bubbles in the glue between the homogenizer and solar cell during adhesion process is reduced. Therefore the optical efficiency is improved, the yield rate of the concentrator solar module is increased and the service life of the concentrator solar module is extended.

In order to achieve the above objects, a concentrator solar receiver with an improved homogenizer of the present invention including a concentrator solar cell, a glue disposed over the concentrator solar cell, and a homogenizer arranged over the glue is brought up. The bottom surface of the homogenizer in contact with the glue is a positively curved surface, a conic solid or a truncated tapered structure.

### BRIEF DESCRIPTION OF THE DRAWINGS

The structure and the technical means adopted by the present invention to achieve the above and other objects can be best understood by referring to the following detailed description of the preferred embodiments and the accompanying drawings, wherein

FIG. 1 is a schematic drawing showing glue-overflow of a prior art;

FIG. 2 is an explosive view of an embodiment of a concentrator solar receiver according to the present invention;

FIG. 3A is a schematic drawing showing a homogenizer of an embodiment according to the present invention;

FIG. 3B is a schematic drawing showing a homogenizer of another embodiment according to the present invention;

FIG. 3C is a schematic drawing showing a homogenizer of a further embodiment according to the present invention;

FIG. 3D is a schematic drawing showing a homogenizer of a further embodiment according to the present invention;

FIG. 4 is a schematic drawing showing a rough surface on the bottom of a homogenizer of an embodiment according to the present invention;

FIG. 5 is a schematic drawing showing a rough surface on the bottom of a homogenizer of another embodiment according to the present invention;

FIG. 6 is a schematic drawing showing a rough surface on the bottom of a homogenizer of a further embodiment according to the present invention.

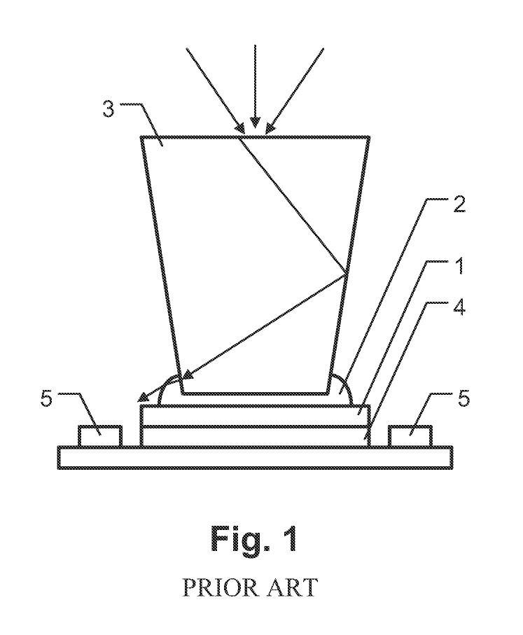

### DETAILED DESCRIPTION OF THE PREFERRED EMBODIMENT

Conventional homogenizers have many problems during adhesion process due to the structural design. In order to solve these problems, an improved homogenizer of the present invention is provided.

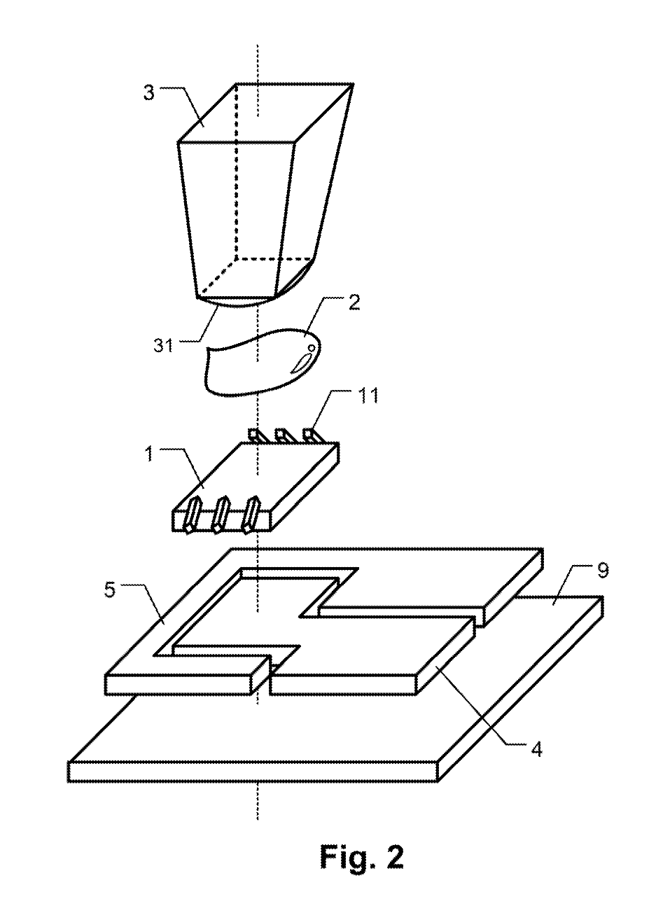

Refer to FIG. 2, an explosive view showing structure and related components is revealed. As shown in figure, a concentrator solar receiver with an improved homogenizer includes a concentrator solar cell 1, a plurality of metal wires 11, a glue 2, a homogenizer 3, a bottom surface 31, a first conductive layer 4, a second conductive layer 5, and an insulating substrate 9.

The homogenizer 3 having the bottom surface 31 thereof is disposed over the sticky glue 2. The glue 2 is arranged over the concentrator solar cell 1. Thus the homogenizer 3 is attached to the concentrator solar cell 1 by the sticky glue 2. For conducting electricity from the concentrator solar cell 1 smoothly, a bottom side of the concentrator solar cell 1 is connected to the first conductive layer 4, and two sides of the concentrator solar cell 1 are arranged with the metal wires 11 to be connected to the second conductive layer 5 to form a current path. Besides, the first conductive layer 4 and the second conductive layer 5 are installed above the insulating substrate 9.

The materials for the homogenizer 3 are not limited. Generally, in order to reduce attenuation during homogenization process of light energy, the homogenizer 3 is made from material with high light transmittance such as glass, quartz, polymethylmethacrylate, (PMMA) or other transparent materials.

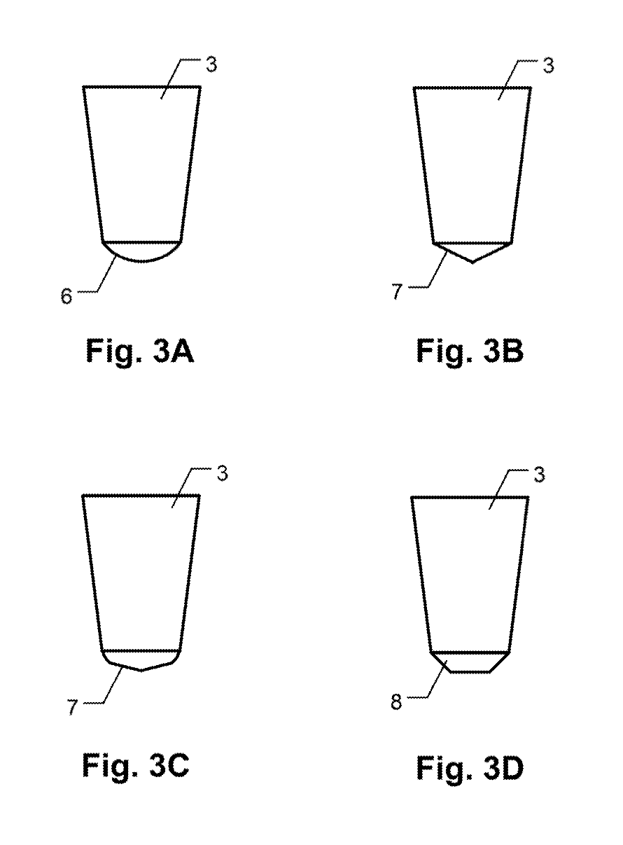

In the present invention, the key technique features on that the bottom surface 31 of the homogenizer 3 is not a smooth flat surface. It has specific shapes and structures. Refer to FIG. 3A, a side view of a cross section of the homogenizer 3 is revealed. Instead of the flat surface, the bottom surface 31 is a positively curved surface 6. The radius of curvature of the positively curved surface 6 is not limited, only allowing the bottom surface 31 of the homogenizer 3 to form a convex surface. In this embodiment, during assembly process of the concentrator solar receiver, the homogenizer 3 is set on the glue 2 more gently due to the positively curved surface 6. The angle between the positively curved surface 6 and the side of the homogenizer 3 is increased so that the glue-overflow generated on periphery is reduced.

Moreover, due to convex structure of the positively curved surface 6 of the bottom surface 31, air between the homogenizer 3 and the glue 2 will be released along the positively curved surface 6 when the homogenizer 3 is in contact with the glue 2, instead of being pressed and staying therebetween to form air bubbles. Thus the possibility of air bubbles remaining in the glue 2 is minimized. Therefore the component damage problem caused by heat expansion of residual air bubbles in the concentrator solar module operating in a high temperature environment can be solved.

Besides the positively curved surface 6, the bottom surface 31 can also be a conic solid 7. The conic solid 7 can be a pyramid or a cone. The conic solid 7 is not necessary to be tapered smoothly from a flat base to a point; it can be a polyhedron with multiple slopes, as shown in FIG. 3C. The design of the conic solid 7 can also solve the glue-overflow problem and eliminate air bubbles.

Furthermore, the bottom surface 31 is made into a truncated tapered structure 8. The truncated tapered structure 8 can be an inverted truncated pyramid or an inverted truncated cone. The cross section of the truncated tapered structure 8 looks like an inverted trapezoid. The slopes on four sides of the tapered structure 8 also help to exhaust air bubbles generated during the adhesion process.

In the present invention, the structural improvement focuses on the bottom surface 31 of the homogenizer 3 without changing other components. The periphery surfaces and the top surface of a main body of the homogenizer 3 may have different shapes so as to be used in different optical designs. Thus there are various types of homogenizers 3. It's not practical to make modification of the periphery surfaces and the top surface of various types of homogenizers 3 to improve the adhesion strength. The improvement of the bottom surface 31 of the present invention can be applied to various types of homogenizers now. Moreover, the concentrator solar cell array can also be upgraded without change of the design.

The structural modification of the bottom surface 31 can solve the problem of glue-flow, increase the adhesion strength and exhaust air bubbles. Moreover, the change of roughness of the bottom surface 31 further improves the adhesion strength of the homogenizer and the stability of the concentrator solar module.

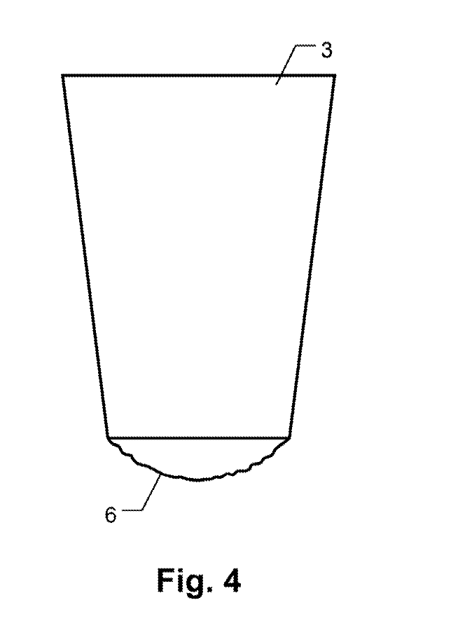

Refer to FIG. 4, the positively curved surface 6 is not a smooth surface. It's a rough surface so that contact area between the positively curved surface 6 and the glue 2 is increased and the adhesion strength is improved.

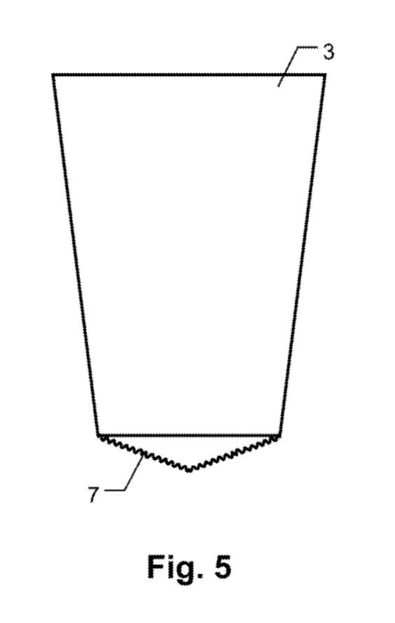

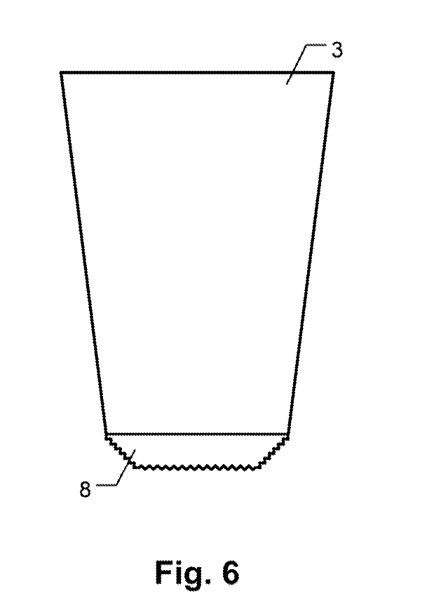

Similarly, refer to FIG. 5 and FIG. 6, when the conic solid 7 or the truncated tapered structure 8 is a rough surface, the homogenizer 3 and the glue 2 are adhered to each other more tightly.

In the concentrator solar receiver with an improved homogenizer of the present invention, the homogenizer is of better adhesion strength during assembly so that the top-heavy homogenizer remains stable, not going to tip over when the sun tracker system works. Thus the service life is extended. Moreover, air bubbles generated during adhesion process can be exhausted. The yield rate is improved. The defects that affect light focus performance or cause damages can be prevented. With multiple functions and excellent performance, the concentrator solar receiver with the improved homogenizer is of great economic value.

Additional advantages and modifications will readily occur to those skilled in the art. Therefore, the invention in its broader aspects is not limited to the specific details, and representative devices shown and described herein. Accordingly, various modifications may be made without departing from the spirit or scope of the general inventive concept as defined by the appended claims and their equivalents.

1. A concentrator solar receiver with a homogenizer comprising:
a solar cell;
a glue disposed over the solar cell; and
a homogenizer arranged over the glue, adhered to the solar cell by the glue and having a bottom surface that is in contact with the glue and is a positively curved surface.

2. The device as claimed in claim 1, wherein the positively curved surface is a rough surface.

3. A concentrator solar receiver with a homogenizer comprising:
a concentrator solar cell;
a glue disposed over the concentrator solar cell; and
a homogenizer arranged over the glue, adhered to the concentrator solar cell by the glue and having a bottom surface that is in contact with the glue and is a conic solid.

4. The device as claimed in claim 3, wherein the conic solid is selected from the group consisting of a cone and a pyramid.

5. The device as claimed in claim 3, wherein the conic solid is having rough surfaces.

6. A concentrator solar receiver with a homogenizer comprising:
a concentrator solar cell;
a glue disposed over the concentrator solar cell; and
a homogenizer arranged over the glue, adhered to the concentrator solar cell by the glue and having a bottom surface that is in contact with the glue and is a truncated tapered structure.

7. The device as claimed in claim 6, wherein the truncated tapered structure is selected from the group consisting of an inverted truncated pyramid or an inverted truncated cone.

8. The device as claimed in claim 6, wherein the truncated tapered structure is having rough surfaces.
